(19) United States
(12) Patent Application Publication
(10) Pub. No.: US 2026/0371534 A1
(43) Pub. Date: Nov. 19, 2026

(54) COOLING SYSTEMS AND METHODS WITH RADIATIVE COOLING

(71) Applicant: TRANE INTERNATIONAL INC., Davidson, NC (US)

(72) Inventors: Zubin VARGHESE, Bangalore (IN); Balegundi L. ROHITH, Bangalore (IN); Praveena Alangar SUBRAHMANYA, Vitla (IN)

(21) Appl. No.: 19/121,966

(22) PCT Filed: Oct. 17, 2023
(86) PCT No.: PCT/IB2023/060467

§ 371 Date: Apr. 17, 2025

(30) Foreign Application Priority Data
Oct. 17, 2022 (IN) 202241059130

(51) Int. Cl. H05K 7/20

(52) U.S. Cl. CPC H05K 7/20827; H05K 7/20309; H05K 7/20318; H05K 7/20327

(57) ABSTRACT

Methods and systems for cooling conditioned spaces (e.g., data centers) are provided.

The cooling system includes a radiative cooling component disposed outside of the housing and including a radiative cooling surface configured to provide radiative cooling directly or indirectly to the working fluid of the internal cooling component, and a thermally coupling component thermally connecting the internal cooling component to the radiative cooling component to transfer heat from the working fluid of the internal cooling component.

### TECHNICAL FIELD

This disclosure relates generally to cooling systems, methods, and designs thereof. More specifically, the disclosure relates to cooling systems and/or methods with radiative cooling, and optionally thermosiphon cooling.

### BACKGROUND

Computer servers and related electronic equipment generate a considerable amount of heat in a relatively small space. The amount of heat output per server varies, depending on configuration. Data centers, as a facility including servers and related equipment for the purpose of storing and processing data and applications, are highly sensitive to temperature and humidity fluctuations. Cooling is a major cost factor in data centers and is often a major limiting factor in data center capacity.

### SUMMARY

There is a desire to effectively remove heat from working fluid in an internal cooling system for a conditioned space (e.g., an immersion cooling system for a data center). Briefly, in one aspect, the present disclosure describes a cooling system for a conditioned space including a housing receiving electronic components and an internal cooling component disposed inside the housing to direct a working fluid in thermal contact with the electronic components to reject heat therefrom. The cooling system includes a radiative cooling component disposed outside of the housing and including a radiative cooling surface configured to provide radiative cooling directly or indirectly to the working fluid of the internal cooling component. The cooling system further includes a thermally coupling component thermally connecting the internal cooling component to the radiative cooling component, and configured to transfer heat from the working fluid of the internal cooling component. In some cases, the thermally coupling component includes a thermosiphon device integrated with the radiative cooling component.

In another aspect, the present disclosure describes a method of cooling a conditioned space including a housing receiving electronic components and an internal cooling component disposed inside the housing to direct a working fluid in thermal contact with the electronic components to reject heat therefrom. The method includes providing a thermally coupling component thermally connecting the internal cooling component to a radiative cooling component disposed outside of the housing, and configured to transfer heat from the working fluid of the internal cooling component. The method further includes providing, via a radiative cooling surface of the radiative cooling component, radiative cooling directly or indirectly to the working fluid of the internal cooling component.

Various advantages are obtained in exemplary embodiments of the disclosure. One such advantage is that the cooling systems and methods can efficiently remove heat from internal cooling mechanisms in a conditioned space (e.g., data centers). Radiative cooling used herein allows heat being rejected into an outer space, mitigating urban heat island effect and reducing energy consumption. In some cases, thermosiphon technology can be adopted to remove heat from the internal cooling mechanisms to transfer to the radiative cooling without pumping working or facility fluids outside the conditioned space.

Various aspects and advantages of exemplary embodiments of the disclosure have been summarized. The above Summary is not intended to describe each illustrated embodiment. Other features and aspects will become apparent by consideration of the following detailed description and accompanying drawings.

### BRIEF DESCRIPTION OF THE DRAWINGS

References are made to the accompanying drawings that form a part of this disclosure and which illustrate the embodiments in which systems and methods described in this specification can be practiced.

FIG. 1 is a block diagram of a cooling system, according to an embodiment.

FIG. 2 is a schematic diagram of a cooling system, according to an embodiment.

FIG. 3 is a schematic diagram of a cooling system, according to an embodiment.

FIG. 4 is a schematic diagram of a modular data center with a cooling system, according to an embodiment.

FIG. 5 is a flow diagram of a method of providing cooling to a data center, according to an embodiment.

FIG. 6A is a schematic diagram of a cooling system including a radiative cooling component and a refrigerant circuit, according to an embodiment.

FIG. 6B is a schematic diagram of a cooling system including a radiative cooling component and a refrigerant circuit, according to an embodiment.

FIG. 7A is a schematic diagram of a cooling system including a radiative cooling component, a refrigerant circuit subsystem, and a thermosiphon component, according to an embodiment.

FIG. 7B is a schematic diagram of a cooling system including a radiative cooling component, a refrigerant circuit subsystem, and a thermosiphon component, according to an embodiment.

FIG. 7C is a schematic diagram of a cooling system including a radiative cooling component, a refrigerant circuit subsystem, and a thermosiphon component, according to an embodiment.

FIG. 8 is a schematic diagram of a cooling system including a radiative cooling component, a refrigerant circuit subsystem, and a thermosiphon component, according to an embodiment.

FIG. 9 is a schematic diagram of a cooling system including a radiative cooling component, a refrigerant circuit subsystem, and a thermosiphon component, according to an embodiment.

FIG. 10 is a schematic diagram of a heat exchanger, according to an embodiment.

### DETAILED DESCRIPTION

This disclosure relates generally to cooling systems, methods, and designs thereof. More specifically, the disclosure relates to cooling systems and/or methods with radiative cooling, and optionally thermosiphon cooling, for a conditioned space (e.g., a data center) including a housing receiving electronic components and an internal cooling component disposed inside the housing to direct a working fluid in thermal contact with the electronic components to reject heat therefrom. The cooling systems and methods described herein can be applied to any suitable types of data center that is a facility including suitable electronic components for the purpose of storing and processing data and applications. It is to be understood that the cooling systems and methods described herein can be applied to any suitable types of cooling other than cooling a data center, such as, for example, cooling a battery pack.

Energy-efficient cooling is critical for more sustainable data center operations. Efficient internal cooling mechanisms such as immersion cooling allows for a much greater density of processing capabilities as compared to airflow cooling using active cooling components such as fans and heat sinks. The cooling systems and methods described herein can efficiently remove heat from the internal cooling mechanisms. Radiative cooling used herein allows heat being rejected into an outer space, mitigating urban heat island effect and reducing energy consumption. In some cases, thermosiphon technology can be adopted to remove heat from the internal cooling mechanisms to transfer to the radiative cooling without pumping working or facility fluids outside the conditioned space.

As used herein, the term “heat exchanger” refers to any heat exchange mechanism or assembly through which a first working fluid (e.g., a coolant) and a second working fluid (e.g., a coolant) can circulate. In some embodiments described herein, the first working fluid may be a dielectric fluid, and the second working fluid may be a liquid coolant such as, for example, water. In some embodiments, the dielectric fluid may be a two-phase dielectric fluid which condenses within the heat exchanger. The heat exchanger may include a facility fluid path and multiple thermally conductive mechanisms (e.g., fins). Size, configuration and construction of the heat exchanger can vary without departing from the scope of the application disclosed herein.

As referenced herein, “thermosiphon” or “thermosiphon device” may refer to a passive heat exchange mechanism that is charged by a working fluid (e.g., a refrigerant such as hydrofluorocarbon (HFC) or haloalkane refrigerant, e.g., R-134a). The working fluid flows (e.g., via its own gravity, or a capillary effect) into the heat exchange mechanism, receives heat from a process fluid at a relatively higher temperature (e.g., an oil from an oil separator), evaporates and exits the heat exchange mechanism (e.g., by means of a pressure gradient, or a capillary effect). The above process continues while the high-temperature process fluid passes through the heat exchange mechanism to transfer heat to the working fluid and drive the process. A thermosiphon device may have a closed or open thermosiphon loop.

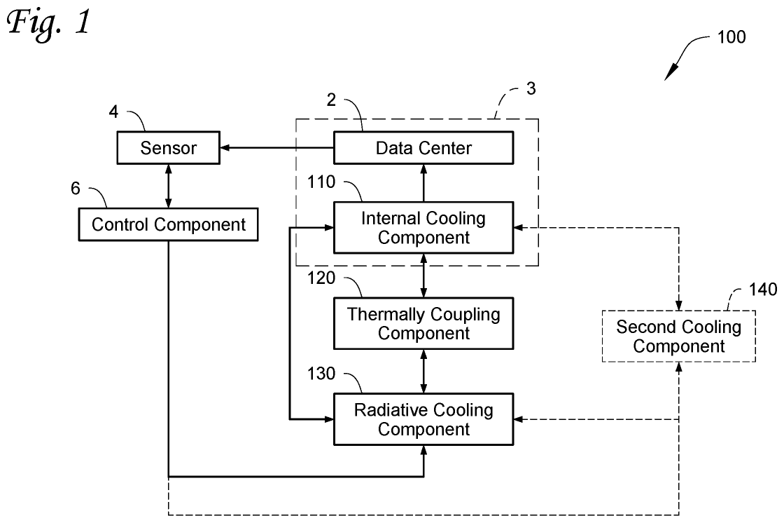

FIG. 1 is a block diagram of a cooling system 100, according to an embodiment. The cooling system 100 is configured to provide cooling to a data center 2. It is to be understood that the cooling system 100 can be applied to any suitable environment/object other than a data center. In some cases, the cooling system 100 can be applied for cooling a battery pack. A data center described herein refers to a facility including various electronic components or other equipment received in a housing (e.g., including one or more enclosures or containers) thereof for the purpose of storing and processing data and applications. An internal cooling component 110 is disposed inside the housing 3 and configured to direct a working fluid in thermal contact with the electronic components inside the housing 3 to reject heat therefrom. The internal cooling component 110 may include at least one of a single-phase immersion cooling system, a two-phase immersion cooling system, or a direct-to-chip cooling system. The cooling system 100 is configured to provide radiative cooling directly or indirectly to the working fluid of the internal cooling component 110. The data center 2 with the internal cooling component 110 and the cooling system 100 may have a power usage effectiveness (PUE) no greater than 1.15, no greater than 1.10, no greater than 1.08, no greater than 1.06, no greater than 1.04, or even no greater than 1.02. PUE is the ratio of total amount of energy used by the data center 2 to the energy delivered to electronic components in the data center 2. One example of PUE can be calculated by the ratio of (server power+pump power)/server power, where the server power is the energy delivered to the servers and the pump power is the energy consumed for pumping working or facility fluids. While a data center is illustrated in FIG. 1, it is to be understood that the internal cooling component 110 can be disposed inside any suitable conditioned space having a housing or container to cool the related equipment received in the conditioned space.

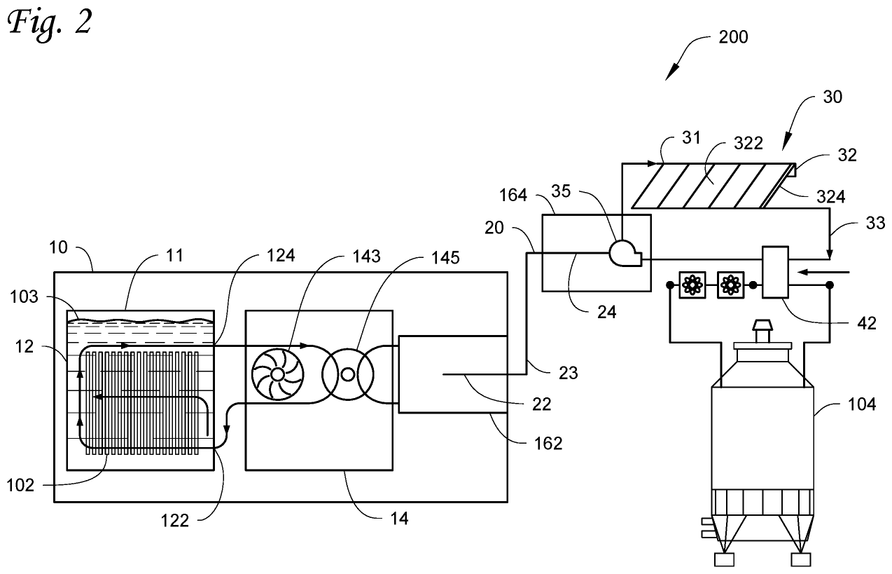

The cooling system 100 further includes a radiative cooling component 130 disposed outside of the housing 3 and including a radiative cooling surface (e.g., a radiative cooling surface 322 of FIG. 2 to be described further below) configured to provide radiative cooling directly or indirectly to the working fluid of the internal cooling component. A thermally coupling component 120 is provided to thermally connect the internal cooling component 110 and the radiative cooling component 130. The thermally coupling component 120 is configured to transfer heat from the working fluid of the internal cooling component, and the transferred heat is then rejected by the radiative cooling provided by the radiative cooling component 130.

In some cases, a working or facility fluid of the internal cooling component 110 can be directed, via the thermally coupling component 120, outside the housing 3 to be directly cooled by the radiative cooling component 130. For example, the thermally coupling component 120 may include a pump, and the working or facility fluid of the internal cooling component 110 can be pumped to the radiative cooling component 130, cooled by the radiative cooling component 130, and returns to the internal cooling component 110. In some cases, the working or facility fluid from the internal cooling component 110 can be indirectly cooled by the radiative cooling component 130, without being directed outside the housing 3. For example, the working or facility fluid of the internal cooling component 110 may have thermal exchange with the thermally coupling component 120 inside the housing 3, and the heat is then transferred, via the thermally coupling component 120, outside to the radiative cooling component 130.

In some cases, the thermally coupling component 120 may include a thermosiphon device or mechanism. The thermosiphon device or mechanism includes an evaporator section at a first end, and a condenser section at a second end opposite the first end. The thermally coupling component 120 may further include an indoor fluid tank to receive a first facility fluid (e.g., water) in thermal exchange with the evaporator section of the thermosiphon component, and an outer door fluid tank to receive a second facility fluid (e.g., water) in thermal exchange with the condenser section of the thermosiphon component. The heated second facility fluid in the outer door fluid tank can be passively cooled by the radiative cooling component 130.

In some cases, the thermally coupling component 120 may not include a thermosiphon device or mechanism to facilitate the heat transfer from the internal cooling component 110 to the radiative cooling component 130. Instead, the heated working fluid or facility fluid from the internal cooling component 110 can be cooled by the radiative cooling provided by the radiative cooling component 130. In some cases, heat from the heated working fluid from the internal cooling component 110 can be first transferred to a first facility fluid (e.g., water) in an indoor fluid tank (e.g., a water tank). The heated first facility water is then pumped to the radiative cooling component 130 to receive radiative cooling and returns to the indoor fluid tank.

The radiative cooling component 130 includes a radiative film or material disposed on the upper surface of a panel as the radiative cooling surface. The radiative film or material can reflect a substantial amount of incident solar light and dissipate heat in the form of radiant energy, for example into the sky. A suitable radiative film or material used herein may have a high reflectivity in solar wavelengths, and a high emissivity in longer infrared wavelengths. The cooling effect from a radiative film or material occurs through a natural phenomenon called radiative cooling. Radiative cooling refers to a process where a body can emit as radiation heat energy absorbed through normal convection and conduction processes. A radiative film or material used herein can have a thickness, for example, between at or about 10 microns and at or about 200 microns, or between at or about 30 microns and at or about 100 microns. One exemplary radiative film may have a multi-layered structure with a thickness of at or about 80 microns. In some embodiments, the radiative films or materials may include a surface coating composition that exhibits low solar absorption and preferential emission at wavelengths corresponding to atmospheric windows in the infra-red regions. Exemplary radiative cooling surface coating compositions are described in U.S. Pat. No. 7,503,971. Exemplary radiative film or material may be commercially available from SkyCool Systems Inc. (Mountain View, CA) under the trade designation of “SkyCool Radiative Cooling Panels.” The base material supporting the radiative film or material can include a thermally conductive material such as, for example, a metal (e.g., aluminum) plate. The structural support may be a combination of wood, steel, fabric, and any other suitable materials. A radiative film or material can passively cool a base material or a substrate underneath the radiative film or material below the ambient temperature with no electricity input, and without evaporating water. In some cases, a radiative film or material can even cool to sub-ambient temperatures while under direct sunlight. In some cases, a passive radiative cooling film may provide net cooling powers (i.e., heat rejection rate) up to, for example, 20 W/m² to 200 W/m², or 100 W/m² to 300 W/m² at an ambient temperature of about 25 °C during daytime and nighttime, respectively, which may cool an underneath substrate by, for example, 1 ° C to 20 °C, or 2 °C to 15 °C below ambient temperature. It is to be understood that the heat rejection rate for a given passive radiative cooling film may vary, depending on ambient conditions such as, for example, the properties of ambient light irradiance (e.g., sunlight, cloud, or the like), temperature, humidity, etc.

The radiative cooling surface of the radiative cooling component 130 has such an area that the cooling capacity of the radiative cooling component 130 can at least partially satisfy the cooling requirement or load of a conditioned space (e.g., the data center 2 in the embodiment depicted in FIG. 1). For example, for a data center having a cooling load of 20 KW, the radiative cooling component 130 may have a radiative cooling surface area of at or about 100 m² to satisfy the data center's cooling needs, assuming the radiative film or material having a heat rejection rate of 200 W/m². It is to be understood that the radiative cooling surface area may depend on the heat rejection rate of the radiative film or material or material and the required cooling requirement or load. In some cases, the radiative cooling component 130 may have a radiative cooling surface area in a range, for example, from at or about 10 m² to at or about 1000 m². In some cases, the radiative cooling component 130 may include an array of radiative film or materials or radiative materials supported by a base material and integrated as a panel.

In some cases, an optional second cooling component 140 can be fluidly connected, e.g., via a three-way vale, to the cooling system 100 to provide additional cooling to the working or facility fluid of the internal cooling component 110 when the cooling capacity of the radiative cooling component 130 alone cannot satisfy the cooling requirements of the data center 2. The second cooling component 140 can include, for example, a cooling tower. When the cooling capacity of the radiative cooling component 130 satisfies the cooling requirement of the data center, the second cooling component 140 (e.g., a cooling tower) can be fluidly disconnected, via the three-way valve, from the internal cooling component 110.

One or more sensors 4 can be provided to monitor the operation conditions of the data center 2 and ambient conditions for the radiative cooling component 130. The sensors 4 may include, for example, one or more of thermostats, humidity sensors, photodetectors, and the like, to collect temperature data, humidity data, and other ambient condition data, or the like, for example at real time. The data center 2 includes various equipment that may be sensitive to temperature and/or humidity fluctuations, which can be monitored by the sensors 4. A control component 6 can collect sensing data from the sensors 4 and determine the cooling requirement or load from the data center 2. The control component 6 can also collect sensing data of the ambient conditions (e.g., sunny, cloudy, daytime, nighttime, etc.) for the radiative cooling component 130 to determine the cooling capacity of the radiative cooling component 130. Depending on the embodiment, the control component 6 may be implemented or realized with a general purpose processor, a microprocessor, a controller, a microcontroller, a state machine, a content addressable memory, an application specific integrated circuit, a field programmable gate array, any suitable programmable logic device, discrete gate or transistor logic, discrete hardware components, or any combination thereof, designed to perform the functions described herein. In this regard, the steps of a method or algorithm described in connection with the embodiments disclosed herein may be embodied directly in hardware, in firmware, in a software module executed by the control component 6, or in any practical combination thereof.

A cooling system described herein (e.g. cooling system 100) may have a retrofit design for various applications. The retrofit design allows various components of the cooling system to be added or removed, to be used together as an assembly, or to be used separately to provide the desired functions of cooling to a conditioned space such as a data center including a housing or container receiving various equipment (e.g., electronic components). In some cases, a cooling system may include a radiative cooling component (e.g. radiative cooling component 130) disposed outside of the housing (e.g. housing 3) and including a radiative cooling surface configured to provide radiative cooling directly or indirectly to the working fluid of an internal cooling component (e.g. internal cooling component 110) disposed inside the housing. The radiative cooling component can be removably added to an existing cooling system including an internal cooling component which is configured to direct the working fluid in thermal contact with the indoor equipment to reject heat therefrom. In some cases, the cooling system may include the internal cooling component as a part of the retrofit design. The internal cooling component can be assembled with other components of the cooling system inside or outside a conditioned space to provide cooling for the conditioned space. In some cases, a thermosiphon mechanism or device can be removably added to the cooling system to thermally connect the internal cooling component to the radiative cooling component, and configured to transfer heat from the working fluid of the internal cooling component. In some cases, instead of using a thermosiphon component, the heated working fluid (e.g., water) can be pumped out of the housing or container, cooled by an outdoor radiative cooling component that can be removably assembled to the internal cooling component along with the thermosiphon mechanism or device.

FIG. 2 is a schematic diagram of a cooling system 200, according to an embodiment. An immersion cooling component 11 is provided to a conditioned space 10. In the depicted embodiment, the conditioned space 10 is a data center where electronic components 102 (e.g., one or more server units or server components, storage, networking equipment, etc.) are directly immersed in a dielectric fluid 103 in an enclosure 12 (e.g., a housing or container) of the immersion cooling component 11. The immersion cooling component 11 of the embodiment depicted in FIG. 2 is a single-phase immersion cooling, where the dielectric fluid 3 remains in its liquid phase, and does not boil or undergo a phase change in a cooling process. One exemplary single-phase liquid coolant is commercially available from GRC (Green Revolution Cooling), Inc. (Austin, TX) under the trade designation of Electrosafe. The enclosure 12 includes a fluid inlet 122 and a fluid outlet 124. It is to be understood that the enclosure 12 may include any suitable fluid manifolds, pipes, lines and/or connectors to direct the dielectric fluid 103 to flow inside the enclosure 12 and reject heat from the electronic components 102. Cooling dielectric fluid 103 enters the enclosure 12 via the fluid inlet 122. Heat from the electronic components 102 is transferred to the dielectric fluid 103. The heated dielectric fluid 103 is directed out of the enclosure 12 via the fluid outlet 124 to a heat exchanger 145, where the dielectric fluid 103 is cooled and cycled back into the enclosure 12 via the fluid inlet 122. One or more pumps 143 are used to direct the flow of the dielectric fluid 103 into and out of the enclosure 12. The pumps 143 and the heat exchanger 145 can be assembled as a coolant distribution unit (CDU) 14. The heat exchanger 145 can include any heat exchange mechanism or assembly through which the dielectric fluid 103 and a second coolant can circulate and exchange heat therebetween. In this embodiment, the second coolant is water circulated from a water tank 162 to cool the heated dielectric fluid 103 via the heat exchanger 145. In some cases, the water tank 162 may have a retrofittable design, where the water tank or other fluid tank(s) can be connected to and dissembled from the CDU 14. In some cases, the enclosure 12, the CDU 14, and the water tank 162 can be assembled and disposed indoor (e.g., inside the conditioned space 10) as the immersion cooling component 11.

The heated water in the water tank 162 is cooled by a thermosiphon cooling mechanism or device 20 without being directed outside the conditioned space 10. A suitable thermosiphon cooling mechanism or device may include an evaporator section where heat is delivered and a condenser section where the heat is released. As one example, the thermosiphon cooling mechanism or device is charged by a pre-determined amount of an appropriate working fluid (e.g., a refrigerant such as hydrofluorocarbon (HFC) or haloalkane refrigerant, e.g., R-134a). The working fluid located in the evaporator section evaporates and goes toward the condenser region (e.g., by means of a pressure gradient), where the working fluid condenses, returning to the evaporator section by means of, for example, gravity. In the depicted embodiment of FIG. 2, the thermosiphon cooling mechanism 20 includes an evaporator section 22 disposed inside the water tank 162 and in thermal exchange with the facility fluid (e.g., water) therein. Water in the water tank 162 receives heat from the heated dielectric fluid 103 from the heat exchanger 145 and boils the refrigerant in the evaporator section 22 of the thermosiphon cooling mechanism 20. The refrigerant vapor is transported, via an adiabatic channel section 23, from the evaporator section 22 to a condenser section 24 of the thermosiphon cooling mechanism 20 disposed inside an outdoor water tank 164. The refrigerant vapor condenses and releases heat at the condenser section 24 and returns to the evaporator section 22 via the adiabatic channel section 23. The adiabatic channel section 23 may include one or more channels (e.g., one or more copper tubes) to form a closed or open thermosiphon loop. Heat from the condenser section 24 of the thermosiphon cooling mechanism 20 is transferred to a facility fluid, e.g., water in the outdoor water tank 164. The heated water is pumped out of the water tank 164 to be cooled by a passive radiative cooling component 30 and/or an optional second cooling component 104 (e.g., a cooling tower) to be described further below.

The passive radiative cooling component 30 includes a radiative cooling surface 322 supported by a panel 32. The radiative cooling surface 322 may include one or more radiative films or materials. The radiative films or materials can be disposed onto a base material or a substrate to form the radiative cooling surface 322, with a structural support to enhance the overall structural integrity of the panel 32. A heat exchanger 324 supported by the panel 32 can be provided in the form of, e.g., fluid channels or coils, underneath the radiative cooling surface 322 and in direct or indirect thermal contact with the radiative films or materials thereof. Facility fluid (e.g., water) from the water tank 164 is directed, e.g., by a pump 35, into the heat exchanger 324 via an inlet 31, is radiatively cooled by the radiative cooling surface 322, and returns to the water tank 164 via an outlet 33. In some cases, a thermal interface material (TIM, e.g., a thermally conductive material such as a metal, a thermal paste, a thermal tape, etc.) can be disposed between the radiative films or materials of the radiative cooling surface 322 and the heat exchanger 324 to enhance the heat exchange therebetween.

Optionally, the second cooling component 104 may be connected to the cooling system 200 to provide additional cooling to the data center 10. In the embodiment depicted in FIG. 2, the second cooling component 104 is a cooling tower which is connected to the outlet 33 of the passive radiative cooling film component 30 via a three-way valve 42. When the indoor cooling load from the electronic components 102 is relatively high, the three-way valve 42 is open to allow the cooling tower 104 to provide additional cooling to the heated water from the water tank 164. The cooling tower 104 can have any suitable structure as a heat exchanger where the heated water from the water tank 164 is circulated and brought into thermal contact with a coolant fluid such as, for example, air to reduce the water's temperature. In one exemplary cooling tower, the heated water can be distributed via water distribution nozzles at the top of the tower. Air is drawn through air-inlet louvers to cause a portion of the heated water to evaporate to remove heat from the water. The heated air is drawn out of the tower and the resulting cold water is circulated back to the water tank 164 via the three-way valve 42. It is to be understood that the cooling tower can have any suitable configurations to cool the water from the water tank 164.

When the indoor cooling load from the electronic components 102 is relatively low, the three-way valve 42 is closed to allow the facility fluid from the radiative cooling component 30 bypassing the cooling tower 104 and directly returning to the water tank 164.

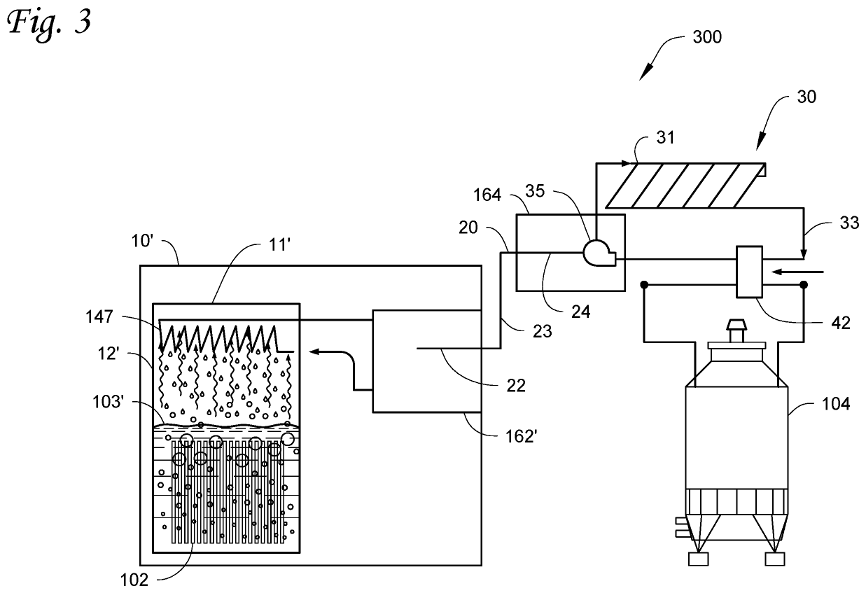

FIG. 3 is a schematic diagram of a cooling system 300, according to an embodiment. The cooling system 300 includes an immersion cooling component 11′ in a conditioned space 10′ (e.g., a data center). The electronic components 102 (e.g., one or more server units or server components) are directly immersed in a dielectric fluid 103′ in an enclosure 12′ of the immersion cooling component 11′. The embodiment depicted in FIG. 3 is a two-phase immersion cooling, where the dielectric fluid 103′ is boiled and condensed to increase heat transfer efficiency. Heat from the hot electronic components 102 causes the fluid 103′ to boil, producing vapor that rises from the liquid. The vapor condenses on a heat exchanger (e.g., a condenser) 147 within the enclosure 12′, transferring heat to facility water that flows from a water tank 162′ outside of the enclosure 12′. It is to be understood that the enclosure 12′ may include any suitable fluid manifolds and lines to direct the dielectric fluid 103′ and the facility water to flow inside the enclosure 12′ and reject heat from the electronic components 102. The heated facility water is then directed from the heat exchanger 147 back to the water tank 162′.

The heat exchanger 147 can include any heat exchange mechanism or assembly through which the vapor of the dielectric fluid 103′ and the facility water can circulate and exchange heat therebetween.

The heated water in the water tank 162′ is cooled by a thermosiphon cooling mechanism 20 without being directed outside the conditioned space 10′. A suitable thermosiphon cooling mechanism may include an evaporator section where heat is delivered and a condenser section where the heat is released. The thermosiphon cooling mechanism is charged for example by a pre-determined amount of an appropriate working fluid (e.g., a refrigerant such as a hydrofluorocarbon (HFC) or haloalkane refrigerant, e.g., R-134a). The working fluid located in the evaporator section evaporates and goes toward the condenser region (e.g., by means of a pressure gradient), where the working fluid condenses, returning to the evaporator section by means of, for example, gravity. In the depicted embodiment of FIG. 3, the thermosiphon cooling mechanism 20 includes an evaporator section 22 disposed inside the water tank 162′ of the indoor immersion cooling component 11′. The heated facility water in the water tank 162′ boils a refrigerant in the evaporator section 22 of the thermosiphon cooling mechanism 20. The refrigerant vapor is transported, via an adiabatic channel section 23, from the evaporator section 22 to a condenser section 24 of the thermosiphon cooling mechanism 20 disposed inside an outdoor water tank 164. The refrigerant vapor condenses and releases heat at the condenser section 24 and returns to the evaporator section 22. Heat from the condenser section 24 of the thermosiphon cooling mechanism 20 is transferred to a facility fluid, e.g., water in the outdoor water tank 164. The heated water is pumped out of the water tank 164 to be cooled by the passive radiative cooling component 30 and/or the optional cooling tower 104 in the same manner as described above for the embodiment depicted in FIG. 2.

In some cases, a direct-to-chip cooling can be used to provide cooling to a data center including the electronic components 102 shown in FIGS. 1 and 2. In a direct-to-chip cooling process, cold plates can be provided to attach to the electronic components. Cooling fluid can be pumped through the cold plates to reject heat from the electronic components. The fluid can include any suitable dielectric fluids, or non-dielectric fluids, used in a single-phase cooling process such as discussed above for FIG. 2, or in a two-phase cooling process such as discussed above for FIG. 3. Exemplary dielectric fluids may be commercially available from 3M Company (St. Paul, MN) under the trade designation of Novec, under the trade designation of Fluorinert (FC-72), and under the trade designation of ElectroCool engineered fluids. Exemplary non-dielectric fluids may include water glycol. The heated fluid from a direct-to-chip cooling can be cooled by the thermosiphon component 20, the radiative cooling component 30, and an optional cooling tower 104 as shown in FIGS. 1 and 2. Referring again to FIG. 2, in a single-phase cooling, the heated fluid from a direct-to-chip cooling can be directed to the coolant distribution unit (CDU) 14. Water circulated from the water tank 162 is used to cool the heated fluid from the direct-to-chip cooling via the heat exchanger 145. The water in the water tank 162 and the water in the water tank 164 are thermally connected by the thermosiphon cooling mechanism 20 to transfer heat without pumping the water from the water tank 162 to the water tank 164. The heated water in the water tank 164 is cooled by the radiative cooling component 30, and optionally, by the cooling tower 104. Referring again to FIG. 3, in a two-phase cooling, the heated fluid (e.g., vapor) from a direct-to-chip cooling can be directed to a heat exchanger (e.g., a condenser 147 in FIG. 3), transferring heat to facility water received by the water tank 162′. The heated water in the water tank 162′ is cooled, via the thermosiphon cooling mechanism 20, by the radiative cooling component 30, and optionally, by the cooling tower 104.

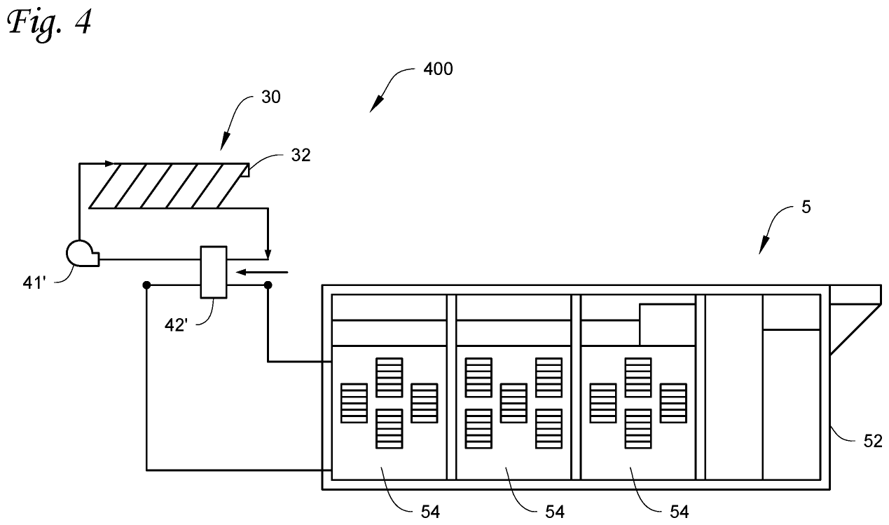

FIG. 4 is a schematic diagram of a modular data center 5 with a cooling system 400, according to an embodiment. The modular data center 5 includes a container 52 to receive a collection of multiple enclosures 54 where electronic components and other equipment are accommodated. In some cases, the container 52 may be standard shipping container that can be portable to a desired location. In some cases, the enclosures 54 may be pre-fabricated pieces that can be fit into a facility built on a site and expanded as needed. Cooling fluid (e.g., a dielectric fluid) can be circulated, via a recycling pump, to the enclosures 54 to provide cooling to the electronic components. The heated fluid from the enclosures 54 is cooled by the cooling system 400. It is to be understood that the modular data center 5 may include any suitable internal cooling component such as, for example, a single-phase immersion cooling system, a two-phase immersion cooling system, or a direct-to-chip cooling system discussed herein. A heat exchanger or a coolant distribution unit (CDU) can be provided to transfer heat from the working fluid of the internal cooling component to a facility fluid. The heated fluid is then directly or indirectly cooled by an outside passive radiative cooling component.

In the depicted embodiment of FIG. 4, the cooling system 400 includes a passive radiative cooling component such as the radiative cooling component 30 shown in FIGS. 1 and 2. The passive radiative cooling component 30 includes a panel 32 of radiative film or material disposed on the top of the container 52. One or more heat exchangers such as the heat exchanger 324 in FIG. 2 can be provided in the form of, e.g., fluid channels or coils, underneath the panel 32 such that an upper surface of the heat exchangers is in direct thermal contact with the panel 32. The heated working fluid or facility fluid from the enclosures 54 of the modular data center 5 can be directed, e.g., by one or more pumps 41′ and/or valves 42′, into the heat exchanger, cooled by the panel 32 of radiative film or material, and return to the enclosures 54.

The cooling fluid provided to the enclosures 54 of the modular data center 5 may include any suitable dielectric fluids, or non-dielectric fluids, used in a single-phase cooling process such as discussed above for FIG. 2, in a two-phase cooling process such as discussed above for FIG. 3, or a direct-to-chip cooling system. The heated fluid from the enclosures 54 can be cooled by the radiative cooling component 30, and optionally, by a cooling tower 104 as shown in FIGS. 1 and 2. Referring to FIG. 4 and again to FIG. 2, in a single-phase cooling, the heated fluid from the enclosures 54 of the modular data center 5 can be directed to the coolant distribution unit (CDU) 14. Water circulated from the water tank 162 is used to cool the heated fluid from the enclosures 54 of the modular data center 5 via the heat exchanger 145. The heated water in the water tank 162 is pumped through the radiative cooling component 30, and the cold water returns to water tank 162. Optionally, the heated water in the water tank 162 may be pumped through a cooling tower such as the cooling tower 104 in FIGS. 1 and 2 to provide additional cooling.

Referring to FIG. 4 and again to FIG. 3, in a two-phase cooling, the heated fluid (e.g., vapor) from the enclosures 54 of the modular data center 5 can be pumped through the radiative cooling component 30, and the cold water returns to the water tank 162′. Optionally, the heated water in the water tank may be pumped through a second cooling component such as, for example, a cooling tower 104 as shown in FIGS. 2-3 to provide additional cooling.

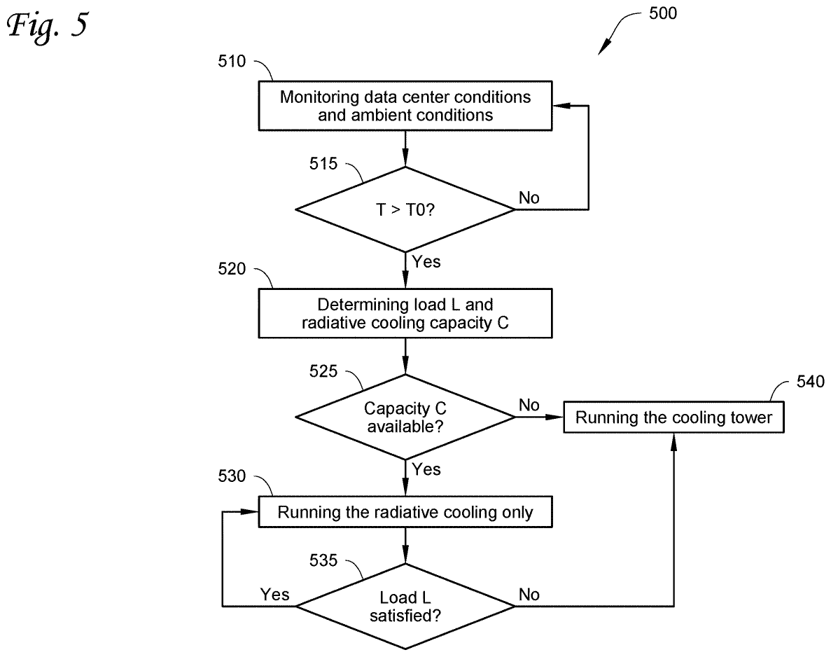

FIG. 5 is a flow diagram of a method 500 of providing cooling to a conditioned space (e.g., a data center), according to one embodiment. The data center can be, for example, an indoor data center such as shown in FIGS. 2 and 3, a modular data center such as shown in FIG. 5, or any other types of data center suitable to be cooled by the cooling systems and methods described herein. The method 500 can be implemented by any suitable cooling systems described herein with a local or remote control mechanism.

At 510, data center conditions and ambient conditions are monitored. Various sensing data can be collected, via sensors such as the sensors 4 in FIG. 1, to monitor conditions such as temperature data (e.g., room temperature, outdoor temperature, etc.) and humidity data (e.g., room humidity, outdoor humidity, etc.) at the data center and ambient conditions (e.g., sunny, cloudy, daytime, nighttime, etc.) for a radiative cooling component. Environmental effects can severely impact data center equipment. For example, excessive heat buildup can damage servers, and may cause them to shut down automatically. In addition, high humidity can lead to condensation, corrosion and contaminants of equipment in the data center. Such environmental effects can be monitored in real time to determine whether to trigger cooling operations.

At 515, when a condition of the data center fails to satisfy predetermined criteria, e.g., the monitored indoor temperature T at the data center is higher than a predetermined value T0, a control component of the cooling system such as the control component 6 of FIG. 1 can instruct the cooling system to start cooling the data center. It will be appreciated that the predetermined criteria may not be the monitored temperature, and can be another monitored, detected condition as previously described (e.g. humidity, data center/ambient conditions, and the like). It will be appreciated that the criteria to trigger cooling can be predetermined based on certain cooling standard for data centers, for example, the thermal and humidity guidelines from the American Society of Heating, Refrigerating and Air-Conditioning Engineers (ASHRAE). ASHRAE recommends the following conditions for a data center: temperatures between 18 and 27 degrees C (64.4 to 80.6 degrees F), dew point of −9 degrees C to 15 degrees C (15.8 to 59 degrees F), and relative humidity of 60%. It is to be understood that the predetermined criteria to trigger cooling may be any suitable operation parameters or their combinations other than a temperature.

At 520, the data center's cooling needs (or load L) and the cooling system's capacity C can be determined, for example in real time. Various system parameters and/or environmental factors such as, for example, the total heat output of the equipment, the floor area, the facility design, air humidity, etc., can be considered to determine the data center's cooling needs. The data center's cooling needs may vary with time, and certain models can be used to predict peak load expectations. The cooling system's capacity C may depend on ambient conditions. For example, a passive radiative cooling component may provide more cooling powers at nighttime than daytime, and more cooling powers at a cloudy day than a sunny day. The cooling system's capacity C may depend on the area of radiative cooling surface to reject heat and its heat rejection rate. In one example, the system may include a radiative cooling panel having a heat rejection rate of up to 200 W/m², and a 20 KW immersion cooling pod may need at or about 100 M² of radiative cooling surface to reject heat and satisfy the data center's cooling needs.

At 525, the control mechanism determines whether the radiative cooling component has a suitable capacity to provide cooling to the data center. When the cooling system has a suitable cooling capacity, the control component instructs to only run the radiative cooling component along with the internal cooling component at 530. When the cooling system does not have a suitable cooling capacity, the control component instructs to run a second cooling component, such as for example a cooling tower along with the internal cooling component at 540.

At 535, the control component determines whether the data center's cooling needs (or load L) has been satisfied by only running the radiative cooling component. When the data center's cooling needs (or load L) has not been satisfied by only running the radiative cooling component along with the internal cooling component, the method 500 proceeds to 540, where the control component instructs to run the optional second cooling component (e.g., a cooling tower) to provide additional cooling for the working fluid of the internal cooling component along with the radiative cooling component. When the data center's cooling needs (or load L) has been satisfied by only running the radiative cooling component along with the internal cooling component, the method 500 proceeds back to 530, where the control component instructs to bypass the optional cooling tower and only run the radiative cooling component to provide cooling for the working fluid of the internal cooling component. In some cases, the control component can instruct one or more valves such as the three-way valve 42 in FIGS. 2 and 3 to be closed or open to include or bypass the optional cooling tower.

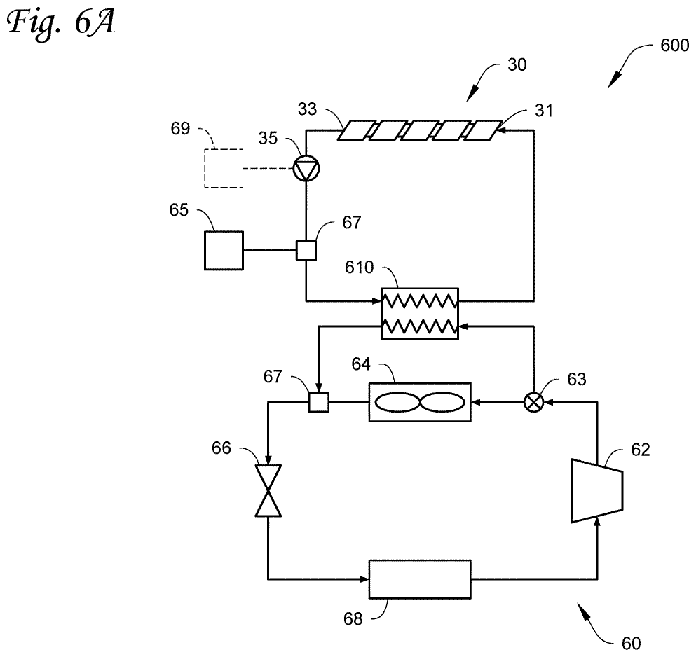

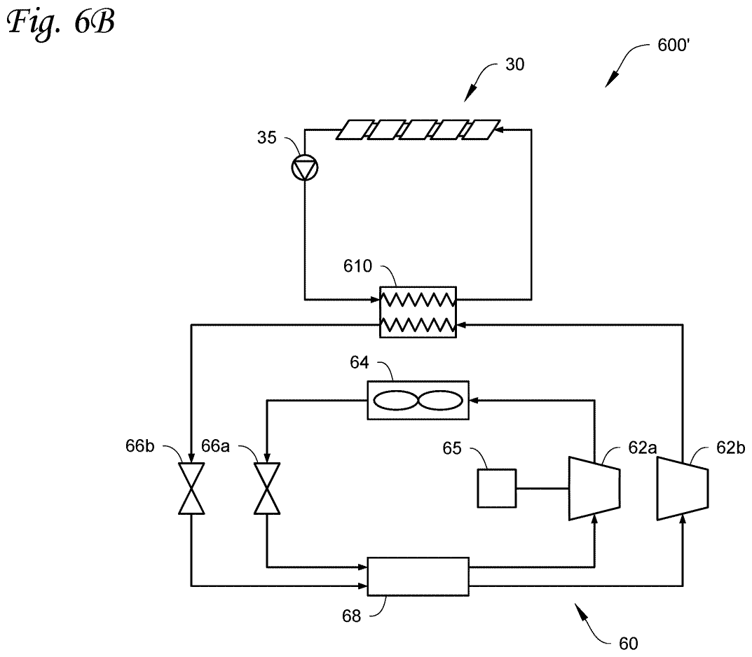

FIG. 6A is a schematic diagram of a cooling system 600 including a radiative cooling component 30 and an active refrigerant circuit 60, according to an embodiment. The active refrigerant circuit 60 includes a first condenser 64 and a second condenser 610 arranged in parallel. The cooled fluid (e.g., water or coolant) from the outlet 33 of the radiative cooling component 30 is routed to the second condenser 610 to cool refrigerant from the refrigerant circuit 60.

In an example embodiment, the active refrigerant circuit 60 can be applied as a thermally coupling component such as the thermally coupling component 120 of FIG. 1. The active refrigerant circuit 60 can be provided to thermally connect an internal cooling component and the radiative cooling component 30 to transfer heat from the working fluid of the internal cooling component, and to reject the heat along with the radiative cooling component 30. It is to be understood that a facility fluid (e.g., hot air, hot water, or the like) from a data center can be directly cooled by the active refrigerant circuit 60.

The active refrigerant circuit 60 includes a compressor 62, condensers 64 and 610, an expansion device 66, and an evaporator 68. The refrigerant circuit 60 further includes a controller 65 (e.g., the control component 6 of FIG. 1) configured to control the operations of the compressor 62, the condensers 64 and 610, the expansion device 66, the evaporator 68, and/or other circuit components of the refrigerant circuit 60 and/or the cooling system 600.

The compressor 60, the condensers 64 and 610, the expansion device 66, and the evaporator 68 can be fluidly connected. An “expansion device” as described herein may also be referred to as an expander. In an embodiment, the expansion device 66 can be an expansion valve, expansion plate, expansion vessel, orifice, or the like, or other such types of expansion mechanisms. It should be appreciated that the expansion device 66 may be any suitable type of expansion device used in the field for expanding a working fluid to cause the working fluid to decrease in pressure and temperature.

The active refrigerant circuit 60 is an example and can be configured to include more or less components. For example, in an embodiment, the active refrigerant circuit 60 can include other components such as, but not limited to, an economizer heat exchanger, one or more flow control devices (e.g., a valve, a pump, or the like), a receiver tank, a dryer, a suction-liquid heat exchanger (e.g., a reheater), or the like.

The active refrigerant circuit 60 can operate according to generally known principles. The active refrigerant circuit 60 can be configured to heat and/or cool a liquid process fluid. The liquid process fluid can be a heat transfer fluid or medium (e.g., a liquid such as, but not limited to, water or the like). In some embodiments, the refrigerant circuit 60 can operate as a vapor-compression circuit such that the compressor 62 compresses a working fluid (e.g., a heat transfer fluid such as, but not limited to, refrigerant or the like) from a relatively lower pressure gas to a relatively higher-pressure gas. The relatively higher-pressure gas is at a relatively higher temperature, being discharged from the compressor 62 and flowing through the condenser 64. In accordance with generally known principles, the working fluid flows through the condenser 62 and rejects heat to the process fluid (e.g., water, air, or the like), thereby cooling the working fluid. The cooled working fluid, which may be in a liquid form, flows to the expansion device 66 that can reduce the pressure of the working fluid. As a result, a portion of the working fluid is converted to a gaseous form. The working fluid, which is now in a mixed liquid and gaseous form flows to the evaporator 68. The working fluid flows through the evaporator 68 and absorbs heat from the process fluid (e.g., a heat transfer medium such as, but not limited to, water, a solution, air, or the like, from a data center), heating the working fluid, and converting it to a gaseous form. In an embodiment, the process fluid is hot air from a data center. The process fluid works as a heat source to evaporate the working fluid. The gaseous working fluid then returns to the compressor 62. The above-described process continues while the heat transfer circuit is operating, for example, in a cooling mode to provide cooling to the data center (e.g., while the compressor 62 is enabled).

The condenser 610 is connected to the active refrigerant circuit 60 in a condenser section thereof, downstream of the compressor 62. The condenser 610 is in parallel to the condenser 64 (e.g., an air-cooled condenser) of the refrigerant circuit 60 via a control valve 63 (e.g., a 3-way directional control valve). The condenser 610 may be a water-cooled condenser such as, for example, a brazed plate heat exchanger (BPHE), a shell and tube heat exchanger, or other suitable types of heat exchanger.

The controller 65 can collect sensor data from one or more sensors to determine coolant/water temperature(s) from the radiative cooling component 30 and/or the active refrigerant circuit 60. In an embodiment, a temperature sensor 67 is disposed at the outlet 33 of the radiative cooling component 30. It is to be understood that one or more sensors can be provided at any suitable locations to determine the working load or status of the radiative cooling component 30 and/or the cooling system 600, 600′.

In an example embodiment, depending on the coolant/water temperature coming from the radiative cooling component 30, the controller 65 can decide portions of refrigerant need to be divided between the condenser 64 and the condenser 610 using the 3-way directional control valve 63. In an example embodiment, one or more sensors 67 can be positioned to monitor the refrigerant temperature(s) coming out from the condenser 610 and/or the condenser 64 to divide the refrigerant using the 3-way directional control valve 63. In the embodiment depicted in FIG. 6A, whichever condenser, the condenser 610 or the condenser 64, has more cooling capacity, the controller 65 can control the system to have that condenser to handle more refrigerant flow from the compressor 62.

The performance of condenser 610 (e.g., BPHE) may be dependent on the radiative cooling component performance (e.g., the outlet coolant temperature from the passive radiative cooling component 30 to the BPHE 610), flow rate of coolant, etc. Similarly, the performance of condenser 64 (e.g., an air-cooled condenser) may be dependent on ambient air temperature, airflow volume (e.g., cubic feet per minute or CFM) across the air-cooled condenser, etc. The controller 65 may collect various sensor data and control the cooling system to reduce usage of the air-cooled condenser 64 (e.g., by reducing fan power consumption) and take more advantage of the passive radiative cooling component 30 to reject heat.

In the embodiment depicted in FIG. 6B, the refrigerant circuit 60 of the cooling system 600′ has a dual-refrigerant-circuit configuration. That is, the refrigerant circuit 60 includes first compressor 62a and second compressor 62b arranged in parallel, first expansion valve 66a and first expansion valve 66b arranged in parallel, the condensers 64 and 610, and the evaporator 68. When the controller 65 determines, based on various sensor data, that sufficiently cooled coolant/water from the radiative cooling component 30 is available, the controller 65 may control the condenser 610 to work with a part load (e.g., with the capacity requirement less than 50%), and the air-cooled condenser 64 may be set at an OFF state. It is to be understood that the condenser 610 (e.g., BHPE) may have a relatively higher efficiency and better performance compared to the condenser 64, which can lead to a higher energy efficiency ratio (EER).

The controller 65 can control the cooling system 600′ to have the condenser 610 to work with a part load, and control the dual-refrigerant-circuit configuration to operate selectively with the first refrigerant circuit (e.g., 62a, 64, 66a and 68, forming an air-cooled system) or the second refrigerant circuit (e.g., 62b, 610, 66b and 68, forming a water-cooled system), depending on the ambient air temperature of the condenser 64, the radiatively cooled water flow rate/temperature of the condenser 610, etc., to gain a maximum EER.

When the part load net capacity requirement is very low (e.g., at or lower than 25% of the full load), the controller 65 can control the heat exchanger 610 to be operational with the radiatively cooled water/coolant, and both compressors 62a and 62b can be OFF to increase the part load efficiency and EER.

It is to be understood that depending on the compressor staging logic, dynamic staging of system can take place considering ambient air temperature and BPHE water entry temperature. For example, refrigerant superheat can be used as a parameter to evaluate and control the performance of a cooling system, for example, as an indication of evaporator performance. “Superheat” may refer to a temperature difference between the temperature of refrigerant vapor at a suction/discharge line of a compressor and its saturation temperature at the corresponding suction/discharge pressure. Superheat can be measured using temperature sensor(s) placed at the suction/discharge line of the compressor. The measured temperature can be compared to the saturation temperature corresponding to the suction/discharge pressure to determine the temperature difference (i.e., superheat). Similar to the using of superheat as the indication of evaporator performance, subcool or subcooling may be used as a parameter to evaluate the performance of condenser(s) or condenser section(s).

The controller 65 can control the operation of the cooling system 600′ based various sensor data. For example, when the controller 65 determines that (i) the heat rejection to the working fluid (e.g., coolant/water) of the radiative cooling component 30 at the heat exchanger 610 and/or (ii) the heat rejection at the evaporator 68 (e.g., to absorb heat from the facility fluid (e.g., hot air or water) from a data center) is not sufficient, the controller 65 can control the system 600′ to turn on the first refrigerant circuit (e.g., the air-cooled system including 62a, 64, 66a and 68) to provide additional cooling at the evaporator 68. When the controller 65 determines that that the cooling of hot air or water at the heat exchanger 610 is sufficient, the controller 65 can control the system 600′ to turn off the first refrigerant circuit (e.g., the air-cooled system including 62a, 64, 66a and 68).

It is also to be understood that two or more active refrigerant circuits (e.g., the active refrigerant circuit 60) may be provided to one or more passive, radiative cooling components (e.g., the radiative cooling component 30) in a cooling system (e.g., the cooling system 600 or 600′). Depending on the installation site condition, suitable numbers of water-cooled system(s) and air-cooled system(s) can be provided to the cooling system, which can be controlled by the controller 65 based on various sensor data collected in the system.

In an embodiment, cold water/coolant generated from the radiative cooling component 30 during nighttime can be stored in an insulated tank. For example, an optional insulated tank 69 is fluidly connected, via the pump 35, to the radiative cooling component 30 to receive cold water/coolant generated therefrom, as shown in FIG. 6A. In an embodiment, the cold water/coolant can be used to freeze a phase change material. During the daytime usage at higher heat load conditions, the stored cold water/coolant generated or the frozen phase change material can be used.

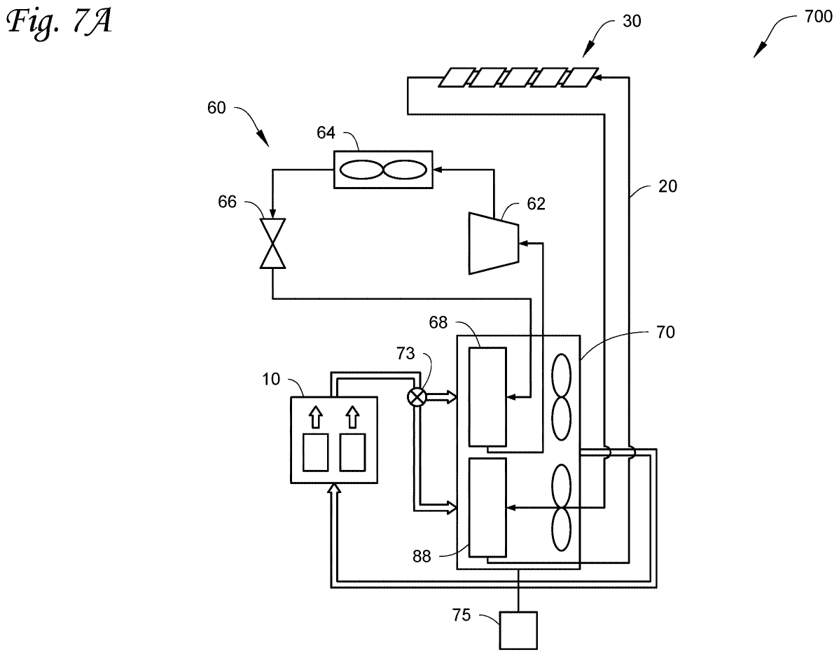

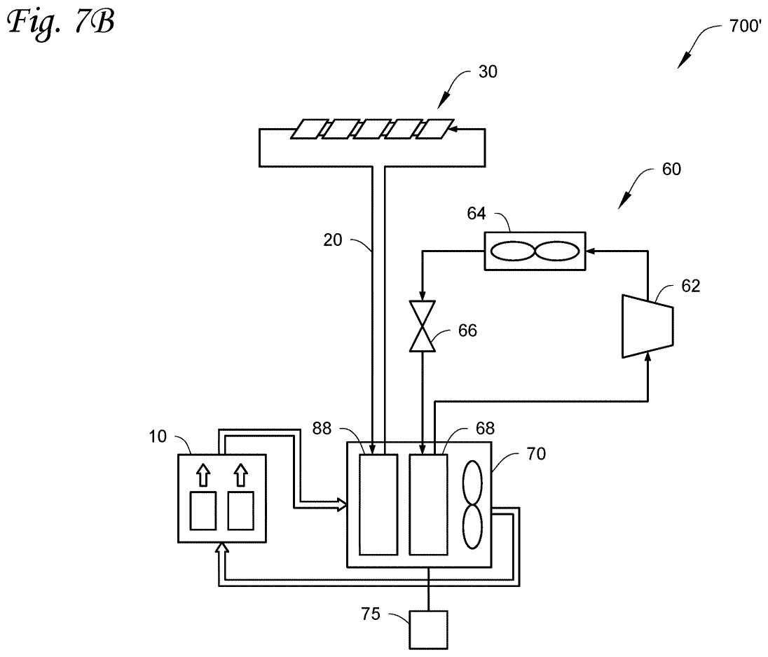

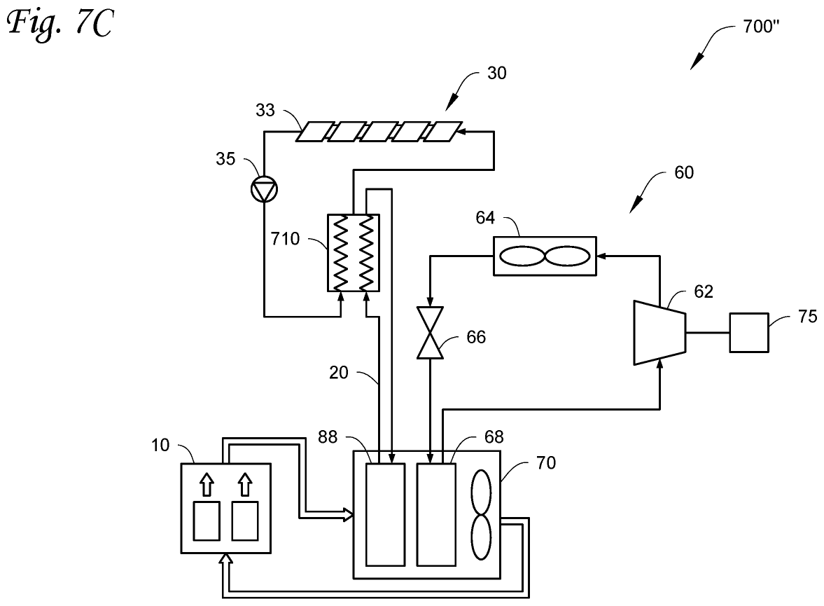

FIG. 7A-C are schematic diagrams of cooling systems 700, 700′, 700″ each including a radiative cooling component 30, an active refrigerant circuit 60, and a thermosiphon component 20, according to some embodiments.

In an example embodiment, the active refrigerant circuit 60 and the thermosiphon component 20 can be applied as a thermally coupling component such as the thermally coupling component 120 of FIG. 1. The active refrigerant circuit 60 and the thermosiphon component 20 can be provided to thermally connect an internal cooling component and the radiative cooling component 30 to transfer heat from the working fluid of the internal cooling component, and to reject the heat along with the radiative cooling component 30. It is to be understood that a facility fluid (e.g., hot air, hot water, or the like) from a data center can be directly cooled by the active refrigerant circuit 60 and/or the thermosiphon component 20. It is to be understood that the respective working fluids of the active refrigerant circuit 60 and the thermosiphon component 20 can circulate within the respective circuits and may not be connected or mixed.

In the cooling system 700 depicted in FIG. 7A, the active refrigerant circuit 60 includes an evaporator 68, and the thermosiphon device 20 includes an evaporator section 88 being arranged to the evaporator 68 of the active refrigerant circuit 60 in parallel. The evaporator 68 is connected to the active refrigerant circuit 60, and the evaporator 88 is connected, via the thermosiphon component 20 to the radiative cooling component 30. The evaporators 68 and 88 can be arranged as a heat exchanger 70.

Heat from hot electronic components of the data center 10 may be transferred to a facility fluid (e.g., water or air). The hot facility fluid can be directed to the heat exchanger 70 which may include any suitable fluid manifolds and lines to direct the facility air or water to flow inside and reject heat from the hot facility air or water. The cooled facility air or water can be directed back to the data center 10.

In the embodiment depicted in FIG. 7A, the heat exchanger 70 includes the first evaporator 68 and the second evaporator 88 which are arranged in parallel to each other, downstream of a control valve 73 (e.g., a 3-way directional control valve). The hot facility fluid from the data center 10 can be divided into the first evaporator 68 and the second evaporator 88, and can be cooled by the active refrigerant circuit 60, and the thermosiphon cooling mechanism or component 20, respectively.

A suitable thermosiphon cooling mechanism may include an evaporator section where heat is delivered and a condenser section where the heat is released. The second evaporator 88 can act as an evaporator section of the thermosiphon component 20. The first evaporator 68 and the second evaporator 88 may each have any suitable configurations to absorb heat from the facility fluid (e.g., hot air or water) from the data center 10. For example, the evaporators 68, 88 may have a fin and tube type heat exchanger configuration, or a microchannel type heat exchanger configuration to absorb heat from hot air from the data center 10. For example, the evaporator 68, 88 may have a BPHE configuration, or a shell and tube type evaporator heat exchanger configuration to absorb heat from hot water from the data center 10. The thermosiphon condenser section may have, for example, a hot wall or skin type heat exchanger configuration, a roll bond type heat exchanger configuration, etc. The thermosiphon component 20 may have its radiative film disposed (e.g., pasted) to one side of sheet facing the sky.

FIG. 7A illustrates the cooling system 700 having the first evaporator 68 of the active refrigeration circuit 60 and the second evaporator 88 of the thermosiphon cooling mechanism 20 arranged in parallel to each other. The hot air or water from the data center 10 can be passed through one or both evaporators 68, 88. The controller 75 can control, via the control valve 73, the amount of hot air or water from the data center 10 to the parallel first and second evaporators 68, 88. In an embodiment, when the controller 75 determines that the cooling of hot air or water from the second evaporator 88 (i.e., the thermosiphon evaporator) is sufficiently enough, the controller 75 can control both evaporator 68 and 88 to have certain hot airflow or water flow from the data center 10. Otherwise, the active refrigeration circuit 60 connected to the first evaporator 68 may have more airflow or water flow from the data center 10 than the passive radiative cooling component 30 connected to the second evaporator 88.

FIG. 7B illustrates the cooling system 700′ having the first evaporator 68 of the active refrigeration circuit 60 and the second evaporator 88 of the thermosiphon cooling mechanism 20 arranged in series. That is, the hot air or water from the data center 10 can pass through the first evaporator 68 and second evaporator 88 (e.g., coils) which are arranged in series. The evaporators 66 and 88 of the cooling system 700′ are arranged in series and may be configured to share fan(s) for air cooling to improve efficiency.

The hot air or water may first get pre-cooled by the second evaporator 88 of the thermosiphon cooling mechanism 20, and then pass through the first evaporator 68 of the active refrigerant circuit 60. The controller 75 can control the operation of the cooling system 700′ based various sensor data. For example, when the controller 75 determines that the cooling of hot air or water from the second evaporator 88 (i.e., the thermosiphon evaporator) is not sufficient, the controller 75 can control turn on the active refrigerant circuit 60 to provide additional cooling at the first evaporator 68. When the controller 75 determines that the cooling of hot air or water from the second evaporator 88 (i.e., the thermosiphon evaporator) is sufficient, the controller 75 can control turn off the active refrigerant circuit 60.

FIG. 7C illustrates the cooling system 700″ where a thermosiphon condenser 710 acts as a cascade heat exchanger. The cooling water or coolant from the outlet 33 of the radiative cooling component 30 is routed, via the pump 35, to the thermosiphon condenser 710 to cool refrigerant from the heat exchanger 70. The thermosiphon condenser 710 can be positioned adjacent to and fluidly connected to the thermosiphon evaporator 88 to form an efficient thermosiphon loop. The thermosiphon condenser 710 can be located relatively closer to the thermosiphon evaporator 88 than to the radiative cooling component 30, which can be beneficial, for example, when the radiative cooling component 30 is located relatively far away from the thermosiphon evaporator 88.

Heat from the data center 10 is absorbed by the first evaporator 68 and the second evaporator 88, which can be arranged in parallel to each other such as shown in the embodiment of FIG. 7A, or arranged in series such as shown in the embodiment of FIG. 7B. After passing through the first evaporator 68, the heat of the hot air or water is then dissipated at the active refrigerant circuit 60. After passing through the second evaporator 88, the heat of the hot air or water is then dissipated at the cascade condenser 710 by the cooling water/coolant circulated in the radiative cooling component 30.

In the embodiments depicted in FIGS. 7A-C, the controller 75 can turn off the active refrigerant circuit 60 when determining that the heat load of the cooling system is less than a predetermined level and the thermosiphon cooling component 30 alone can cool the hot air or water from the data center 10 to a desired temperature. It is to be understood that the controller 75 can control the operations of systems based on various sensor data collected for the systems 700, 700′ and 700″.

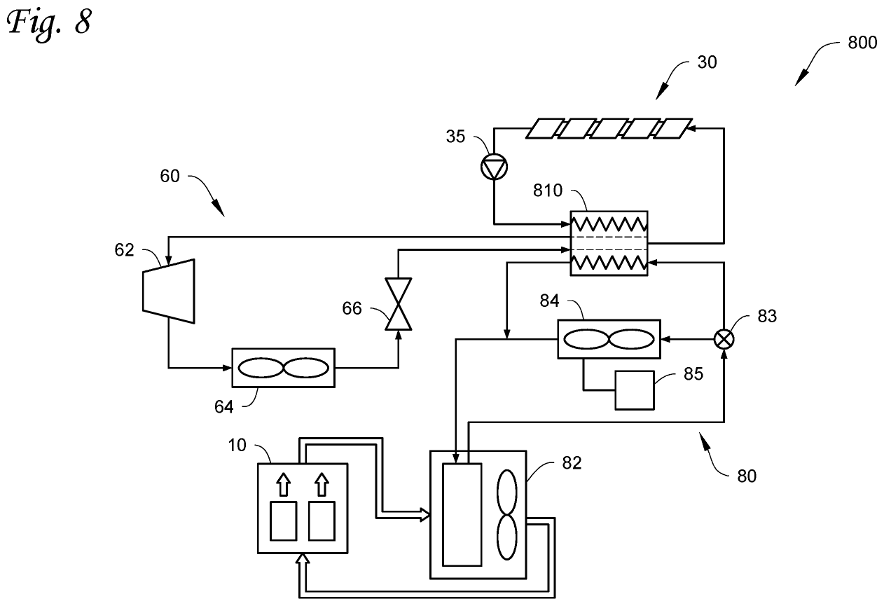

FIG. 8 is a schematic diagram of a cooling system 800 including a radiative cooling component 30, an active refrigerant circuit 60, and a thermosiphon component 80, according to an embodiment.

In an example embodiment, the active refrigerant circuit 60 and the thermosiphon component 80 can be applied as a thermally coupling component such as the thermally coupling component 120 of FIG. 1. The active refrigerant circuit 60 and the thermosiphon component 80 can be provided to thermally connect an internal cooling component and the radiative cooling component 30 to transfer heat from the working fluid of the internal cooling component, and to reject the heat along with the radiative cooling component 30. It is to be understood that a facility fluid (e.g., hot air, hot water, or the like) from a data center can be directly cooled by the thermosiphon component 80.

The cooling system 800 includes a cascade heat exchanger 810 which may have a 3-fluid heat exchange configuration. An example of the cascade heat exchanger 810 is a brazed plate heat exchanger (BPHE) capable of 3-fluid cascade heat exchange (e.g., first fluid from the radiative cooling component 30, second fluid from active refrigerant circuit 60, and third fluid from the thermosiphon evaporator 82). The cascade heat exchanger 810 may have any other suitable configurations. For example, in an example embodiment, the cascade heat exchanger 810 may be a shell and tube heat exchanger including two sets of tubes carrying refrigerants from the active refrigeration circuit 60 and the thermosiphon component, respectively. In another example embodiment, the cascade heat exchanger 810 may include a shell side on which the refrigerant from the thermosiphon component 80 is in a vapor state. The vapor state refrigerant may be thermally in direct contact with (i) one set of tubes which carries the refrigerant of the active refrigerant circuit 60 and (ii) another set of tubes which carries the coolant/water from the radiative cooling component 30. In some embodiments, a shell side of the shell and tube heat exchanger 810 may be filled with coolant which can be circulated to the radiative cooling component 30.

Hot air or water from the data center 10 can be cooled by the evaporator 82 of the thermosiphon component 80. Heat absorbed by the thermosiphon evaporator 82 can be rejected at the cascade heat exchanger 810 and/or the thermosiphon condenser 84 (e.g., an air cooled heat exchanger). The heat exchanger 810 and/or the thermosiphon condenser 84 are arranged in parallel to each other, downstream of a control valve 83 (e.g., a 3-way directional control valve). The thermosiphon condenser 84 can be connected to the thermosiphon evaporator 82 to form a thermosiphon loop.

A controller 85 may collect sensing data from sensor(s) located downstream of the thermosiphon condenser 84 or the cascade heat exchanger 810 to determine whether the associated condensation is complete or not (e.g., by calculating sub-cooling). When the controller 85 determines that the thermosiphon condenser 84 is not condensing all refrigerant from the thermosiphon evaporator 82, the controller 85 can control the 3-way directional control valve 83 to direct certain amount of refrigerant to the cascade heat exchanger 810. At the cascade heat exchanger 810, the radiative cooling component 30 can pass, via the pump 35, cold water/coolant through the cascade heat exchanger 810 to absorb the heat from the refrigerant of thermosiphon component 80 and condense the refrigerant. When the controller 85 determines that the capacity of the radiative cooling component 30 is not sufficient to cool the refrigerant at the heat exchanger 810, the controller 85 can turn on the active refrigerant circuit 60 to cool the refrigerant of the thermosiphon component 80 at the cascade heat exchanger 810. In the embodiment depicted in FIG. 8, the active refrigerant circuit 60 includes the compressor 62, the condenser 64, the expansion device 66, and an evaporator section including at least a portion of the cascade heat exchanger 810.

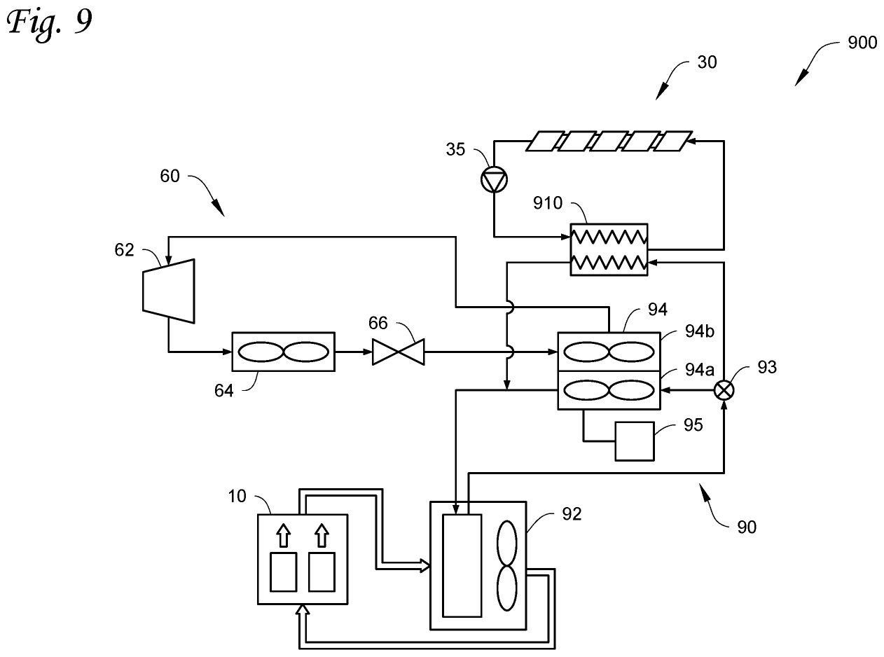

FIG. 9 is a schematic diagram of a cooling system 900 including a radiative cooling component 30, an active refrigerant circuit 60, and a thermosiphon component 90, according to an embodiment.

In an example embodiment, the active refrigerant circuit 60 and the thermosiphon component 90 can be applied as a thermally coupling component such as the thermally coupling component 120 of FIG. 1. The active refrigerant circuit 60 and the thermosiphon component 90 can be provided to thermally connect an internal cooling component and the radiative cooling component 30 to transfer heat from the working fluid of the internal cooling component, and to reject the heat along with the radiative cooling component 30. It is to be understood that a facility fluid (e.g., hot air, hot water, or the like) from a data center can be directly cooled by the thermosiphon component 90.

In the embodiment depicted in FIG. 9, hot air or water from the data center 10 can transfer heat to an evaporator 92 of the thermosiphon component 90. The evaporator 92 may be, for example, an air-to-refrigerant heat exchanger. The refrigerant of the evaporator 92 is evaporated and condensed at (i) a condenser 94a (e.g., air cooled) of the thermosiphon component 90 and/or (ii) at a condenser 910 which is cooled by the radiative cooling component 30.

When the controller 95 determines that the radiative cooling capacity of the passive radiative cooling component 30 is not sufficient, the controller 95 can control the 3-way valve 93 to direct certain amounts of refrigerant to the thermosiphon condenser 94a (e.g., air-cooled).

When the controller 95 determines that the capacity of the radiative cooling component 30 and the thermosiphon condenser 94a (e.g., air-cooled) together may not be sufficient, the controller 95 can turn on the active refrigerant circuit 60 to provide active cooling at the evaporator 94b of the active refrigerant circuit 60. In the embodiment depicted in FIG. 9, the active refrigerant circuit 60 includes the compressor 62, the condenser 64, the expansion device 66, and an evaporator section including at least a portion of the evaporator 94b.

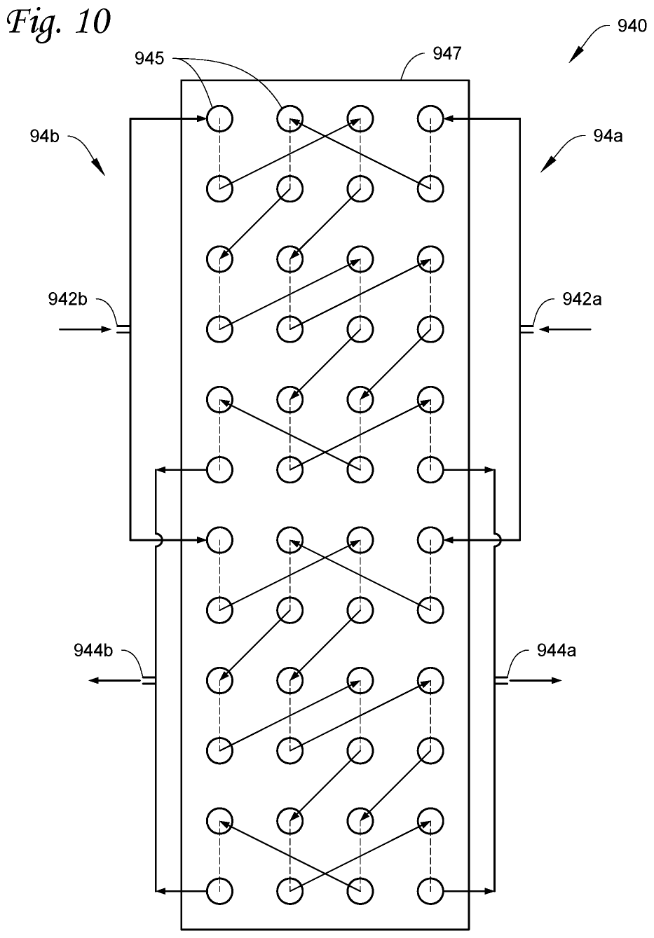

In the embodiment depicted in FIG. 9, the thermosiphon condenser 94a (e.g., air cooled) and the evaporator 94b of the active refrigerant circuit 60 may be arranged as a heat exchanger 94 which may be shared by the active refrigerant circuit 60 and the thermosiphon component 90. In an example embodiment, the heat exchanger 94 may have an interlaced or intertwined coil arrangement. FIG. 10 is a schematic diagram illustrating an example heat exchanger 940 having an intertwined or interlaced configuration. The heat exchanger 940 includes an array of tubes 945 thermally connected to one or more fins 947 to form tube circuitry, which can be shared by the thermosiphon condenser 94a and the evaporator 94b. The thermosiphon condenser 94a includes an inlet 942a and an outlet 944a fluidly connected to the tube circuitry, and the evaporator 94b includes an inlet 942b and an outlet 944b fluidly connected to the tube circuitry. It is to be understood that the heat exchanger 94 may any suitable interlaced or intertwined configurations. It is also to be understood that the respective working fluids of the evaporator 94b of the active refrigerant circuit 60 and the condenser 94a of the thermosiphon component 20 can circulate within the respective circuits and may not be connected or mixed in the heat exchanger 94.

When the thermosiphon condenser 94a is active, a fan thereof can be turned on to provide air cooling, e.g., to condense thermosiphon refrigerant inside tubes. When the active evaporator 94b is turned on, the fan of the air-cooled thermosiphon condenser 94a can be turned off, and heat exchange between the thermosiphon condenser 94a (e.g., a first set of thermosiphon refrigerant tubes) and the active evaporator 94b (e.g., a second set of circuit refrigerant tubes) may be conducted through the fins of coil which thermally connects both sets of tubes with an interlaced arrangement. It is to be understood that the heat exchanger 94 may have any suitable configurations to facilitate the cooling of thermosiphon refrigerant at the thermosiphon condenser 94a using the active refrigerant circuit 60 and/or ambient air. In an example embodiment, the heat exchanger 94 may include an interlaced heat exchanger, for which an enclosure can be provided to isolate or reduce the ambient air or heat load interaction. When the thermosiphon condenser 94a is active or working and the active refrigerant circuit 60 is turned off, a fan can blow the ambient air to the interlaced heat exchanger.

### Aspects

It is appreciated that any one of aspects 1 to 10 can be combined with any of aspects 11-20.

Aspect 1 is a cooling system for a conditioned space including a housing receiving electronic components and an internal cooling component disposed inside the housing to direct a working fluid in thermal contact with the electronic components to reject heat therefrom, the cooling system comprising:
a radiative cooling component disposed outside of the housing and including a radiative cooling surface configured to provide radiative cooling directly or indirectly to the working fluid of the internal cooling component; and
a thermally coupling component thermally connecting the internal cooling component to the radiative cooling component, and configured to transfer heat from the working fluid of the internal cooling component.

Aspect 2 is the cooling system of aspect 1, wherein the thermally coupling component includes a thermosiphon device.

Aspect 3 is the cooling system of aspect 2, wherein the thermosiphon device includes an evaporator section at a first end, and a condenser section at a second end opposite the first end.

Aspect 4 is the cooling system of aspect 3, further comprising a first fluid tank to receive a facility fluid in thermal exchange with the evaporator section of the thermosiphon device.

Aspect 5 is the cooling system of aspect 3 or 4, further comprising a second fluid tank to receive a facility fluid in thermal exchange with the condenser section of the thermosiphon device.

Aspect 6 is the cooling system of any one of aspects 1-5, wherein the radiative cooling surface of the radiative cooling component has a heat rejection rate in a range from 100 W/m² to 300 W/m² at an ambient temperature about 25 °C

Aspect 7 is the cooling system of any one of aspects 1-6, wherein the conditioned space is a data center.

Aspect 8 is the cooling system of any one of aspects 1-7, further comprising a three-way valve to fluidly connect a second cooling component to the internal cooling component to provide additional cooling to the working fluid of the internal cooling component.

Aspect 9 is the cooling system of any one of aspects 1-8, wherein the internal cooling component includes at least one of a single-phase immersion cooling system, a two-phase immersion cooling system, or a direct-to-chip cooling system.

Aspect 10 is the cooling system of any one of aspects 1-9, further comprising a control component configured to determine whether a cooling capacity of the radiative cooling component satisfies a cooling requirement of the conditioned space.

Aspect 11 is a method of cooling a conditioned space including a housing receiving electronic components and an internal cooling component disposed inside the housing to direct a working fluid in thermal contact with the electronic components to reject heat therefrom, the method comprising:
providing a thermally coupling component thermally connecting the internal cooling component to a radiative cooling component disposed outside of the housing, and configured to transfer heat from the working fluid of the internal cooling component; and
providing, via a radiative cooling surface of the radiative cooling component, radiative cooling directly or indirectly to the working fluid of the internal cooling component.

Aspect 12 is the method of aspect 11, wherein the thermally coupling component includes a thermosiphon device to facilitate the radiative cooling indirectly to the working fluid of the internal cooling component.

Aspect 13 is the method of aspect 12, wherein the thermosiphon device includes an evaporator section at a first end, and a condenser section at a second end opposite the first end.

Aspect 14 is the method of aspect 13, wherein the evaporator section of the thermosiphon device is in thermal exchange with a facility fluid in a first fluid tank.

Aspect 15 is the method of aspect 13 or 14, wherein the condenser section of the thermosiphon device is in thermal exchange with a facility fluid in a second fluid tank.

Aspect 16 is the method of any one of aspects 11-15, further comprising monitoring conditioned space conditions and ambient conditions including collecting real-time temperature and humidity data.

Aspect 17 is the method of any one of aspects 11-16, further comprising determining whether a cooling capacity of the radiative cooling component satisfies a cooling requirement of the conditioned space.

Aspect 18 is the method of aspect 17, further comprising providing additional cooling, via a second cooling component, to the working fluid of the internal cooling component when the cooling capacity of the radiative cooling component does not satisfy the cooling requirement of the conditioned space.

Aspect 19 is the method of aspect 18, further comprising fluidly disconnecting, via a three-way valve, the second cooling component from the internal cooling component when the cooling capacity of the radiative cooling component satisfying the cooling requirement of the conditioned space.

Aspect 20 is the method of any one of aspects 11-19, wherein the internal cooling component includes at least one of a single-phase immersion cooling system, a two-phase immersion cooling system, or a direct-to-chip cooling system.

Aspect 21 is the cooling system of any one of aspects 1-10, wherein the thermally coupling component includes an active refrigerant circuit including a first condenser and a second condenser arranged in parallel.

Aspect 22 is the cooling system of aspect 21, wherein the active refrigerant circuit has a dual-refrigerant-circuit configuration.

Aspect 23 is the cooling system of any one of aspects 1-10 and 21-22, wherein the thermally coupling component includes an active refrigerant circuit and a thermosiphon device, the active refrigerant circuit including an evaporator, the thermosiphon device including an evaporator section being arranged in parallel to the evaporator of the active refrigerant circuit.

Aspect 24 is the cooling system of any one of aspects 1-10 and 21-23, wherein the thermally coupling component includes an active refrigerant circuit and a thermosiphon device, the active refrigerant circuit including an evaporator, the thermosiphon device including an evaporator section being arranged in series with the evaporator of the active refrigerant circuit.

Aspect 25 is the cooling system of any one of aspects 1-10 and 21-24, wherein the thermally coupling component includes an active refrigerant circuit and a thermosiphon device, the active refrigerant circuit including an evaporator, the thermosiphon device including an evaporator section and a condenser section, the evaporator section being connected to the evaporator of the active refrigerant circuit, and the condenser section being connected to the radiative cooling component.

Aspect 26 is the cooling system of any one of aspects 1-10 and 21-25, wherein the thermally coupling component includes a thermosiphon device, an active refrigerant circuit, and a cascade heat exchanger to conduct heat exchange among the thermosiphon device, the active refrigerant circuit, and the radiative cooling component, the cascade heat exchanger being connected to a condenser section of the thermosiphon device in parallel.

Aspect 27 is the cooling system of any one of aspects 1-10 and 21-26, wherein the thermally coupling component includes a thermosiphon device, an active refrigerant circuit, and a heat exchanger acting as an evaporator of the active refrigerant circuit and a condenser section of the thermosiphon device.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

1-27. (canceled)

28. A cooling system for a conditioned space including a housing receiving electronic components and an internal cooling component disposed inside the housing to direct a working fluid in thermal contact with the electronic components to reject heat therefrom, the cooling system comprising:
a radiative cooling component disposed outside of the housing and including a radiative cooling surface configured to provide radiative cooling directly or indirectly to the working fluid of the internal cooling component; and
a thermally coupling component thermally connecting the internal cooling component to the radiative cooling component, and configured to transfer heat from the working fluid of the internal cooling component.

29. The cooling system of claim 28, wherein the thermally coupling component includes a thermosiphon device.

30. The cooling system of claim 29, wherein the thermosiphon device includes an evaporator section at a first end, and a condenser section at a second end opposite the first end.

31. The cooling system of claim 28, wherein the radiative cooling surface of the radiative cooling component has a heat rejection rate in a range 100 W/m² to 300 W/m² at an ambient temperature about 25 °C.

32. The cooling system of claim 28, wherein the conditioned space is a data center.

33. The cooling system of claim 28, further comprising a three-way valve to fluidly connect a second cooling component to the internal cooling component to provide additional cooling to the working fluid of the internal cooling component.

34. The cooling system of claim 28, wherein the internal cooling component includes at least one of a single-phase immersion cooling system, a two-phase immersion cooling system, or a direct-to-chip cooling system.

35. The cooling system of claim 28, further comprising a control component configured to determine whether a cooling capacity of the radiative cooling component satisfies a cooling requirement of the conditioned space.

36. A method of cooling a conditioned space including a housing receiving electronic components and an internal cooling component disposed inside the housing to direct a working fluid in thermal contact with the electronic components to reject heat therefrom, the method comprising:
providing a thermally coupling component thermally connecting the internal cooling component to a radiative cooling component disposed outside of the housing, and configured to transfer heat from the working fluid of the internal cooling component; and
providing, via a radiative cooling surface of the radiative cooling component, radiative cooling directly or indirectly to the working fluid of the internal cooling component.

37. The method of claim 36, wherein the thermally coupling component includes a thermosiphon device to facilitate the radiative cooling indirectly to the working fluid of the internal cooling component.

38. The method of claim 36, further comprising monitoring conditioned space conditions and ambient conditions including collecting real-time temperature and humidity data.

39. The method of claim 36, further comprising determining whether a cooling capacity of the radiative cooling component satisfies a cooling requirement of the conditioned space.

40. The method of claim 39, further comprising providing additional cooling, via a second cooling component, to the working fluid of the internal cooling component when the cooling capacity of the radiative cooling component does not satisfy the cooling requirement of the conditioned space.

41. The method of claim 40, further comprising bypassing the second cooling component when the cooling capacity of the radiative cooling component satisfying the cooling requirement of the conditioned space.

42. The method of claim 36, wherein the internal cooling component includes at least one of a single-phase immersion cooling system, a two-phase immersion cooling system, or a direct-to-chip cooling system.

43. The cooling system of claim 28, wherein the thermally coupling component includes an active refrigerant circuit including a first condenser and a second condenser arranged in parallel.

44. The cooling system of claim 28, wherein the thermally coupling component includes an active refrigerant circuit and a thermosiphon device, the active refrigerant circuit including an evaporator, the thermosiphon device including an evaporator section being arranged in parallel to the evaporator of the active refrigerant circuit.

45. The cooling system of claim 28, wherein the thermally coupling component includes an active refrigerant circuit and a thermosiphon device, the active refrigerant circuit including an evaporator, the thermosiphon device including an evaporator section being arranged in series with the evaporator of the active refrigerant circuit.

46. The cooling system of claim 28, wherein the thermally coupling component includes an active refrigerant circuit and a thermosiphon device, the active refrigerant circuit including an evaporator, the thermosiphon device including an evaporator section and a condenser section, the evaporator section being connected to the evaporator of the active refrigerant circuit, and the condenser section being connected to the radiative cooling component.

47. The cooling system of claim 28, wherein the thermally coupling component includes a thermosiphon device, an active refrigerant circuit, and a cascade heat exchanger to conduct heat exchange among the thermosiphon device, the active refrigerant circuit, and the radiative cooling component, the cascade heat exchanger being connected to a condenser section of the thermosiphon device in parallel.
